(19) United States
(12) Patent Application Publication
(10) Pub. No.: US 2016/0186320 A1
(43) Pub. Date: Jun. 30, 2016

(54) APPARATUS FOR CONTINUOUSLY FORMING A FILM THROUGH CHEMICAL VAPOR DEPOSITION

(71) Applicant: METAL INDUSTRIES RESEARCH AND DEVELOPMENT CENTRE, Kaohsiung (TW)

(72) Inventors: Ting-Pin Cho, Kaohsiung (TW); Wen-Cheng Kuo, Kaohsiung (US); Kung-Ming Hsu, Kaohsiung (TW); Ji-Hua Yang, Kaohsiung (TW); Ho-Chung Fu, Kaohsiung (TW)

(21) Appl. No.: 14/583,323

(22) Filed: Dec. 26, 2014

(51) Int. Cl. C23C 16/455; C23C 16/458; C23C 16/448

(52) U.S. Cl. CPC C23C 16/45519; C23C 16/45502; C23C 16/4485; C23C 16/458

(57) ABSTRACT

An apparatus for continuously forming a film through chemical vapor deposition includes a conveyor unit, a depositing unit and a cooling mechanism. The conveyor unit is for conveying a substrate along a moving path. The depositing unit includes at least one deposition chamber disposed to deposit a film-forming material on the substrate. The cooling mechanism includes inlet and outlet cooling units that are disposed oppositely relatively to the deposition chamber, that are communicated fluidly with the deposition chamber and that are controllable to provide a cooling temperature preventing the film-forming material from escaping and scattering away from the inlet and outlet cooling units.

### FIELD OF THE INVENTION

The invention relates to an apparatus for continuously forming a film, and more particularly to an apparatus for continuously forming a film through chemical vapor deposition.

### BACKGROUND OF THE INVENTION

Conventionally, coating of poly-para-xylylene (also called parylene) is usually conducted using chemical vapor deposition (CVD) techniques. Referring to FIG. 1, a conventional apparatus for forming a parylene film on a substrate is shown to include a material vaporizer 11, a material decomposition tube 12 communicated fluidly with the material vaporizer 11, a deposition chamber 13 communicated fluidly with the material decomposition tube 12, a cold trap tube 14 communicated fluidly with the deposition chamber 13, and a vacuum pump 15 coupled to the cold trap tube 14.

When in use, parylene precursors (i.e., solid di-para-xylylene) are placed in the material vaporizer 11, followed by heating to 150° C. to generate vaporized parylene dimers. Thereafter, the vaporized parylene dimers are introduced into the material decomposition tube 12 and are heated at 650° C. to induce pyrolysis of the vaporized parylene dimers to form vaporized parylene monomers (i.e., para-xylylene). The vaporized parylene monomers are then introduced into the deposition chamber 13, which is at ambient temperature, to form the parylene film on a substrate 100 placed in the deposition chamber 13 (multiple ones are shown in FIG. 1). The unreacted parylene monomers are then collected at the cold trap tube 14 by performing condensation therein.

However, the substrate 100, which needs to be placed in the deposition chamber 13 for forming the parylene film, can only be deposited in a batch-by-batch manner, resulting in relatively low production efficiency.

### SUMMARY OF THE INVENTION

Therefore, the object of the present invention is to provide an apparatus that may alleviate the aforementioned drawback in association with the prior art.

According to certain embodiments of the present invention, an apparatus for continuously forming a film through chemical vapor deposition includes a conveyor unit, at least one depositing unit and a cooling mechanism.

The conveyor unit is for conveying a substrate along a moving path.

The depositing unit includes a deposition chamber disposed on the moving path to deposit a film-forming material on the substrate.

The cooling mechanism includes an inlet cooling unit communicated fluidly with the deposition chamber, and an outlet cooling unit communicated fluidly with the deposition chamber. The inlet and outlet cooling units are respectively disposed at two opposite sides of the deposition chamber and are controllable to provide a cooling temperature that prevents the film-forming material from escaping and scattering away from the inlet and outlet cooling units. The conveyor unit may convey the substrate consecutively to pass through the inlet cooling unit, the deposition chamber and the outlet cooling unit so that the film-forming material is able to deposit on the substrate in the deposition chamber.

### BRIEF DESCRIPTION OF THE DRAWINGS

Other features and advantages of the present invention will become apparent in the following detailed description of the exemplary embodiments with reference to the accompanying drawings, of which:

FIG. 1 is a schematic diagram of a conventional apparatus for coating parylene;

FIG. 2 is a schematic sectional view of a first exemplary embodiment of an apparatus for continuously forming a film through chemical vapor deposition according to the present invention;

FIG. 3 is an enlarged sectional view of a part of the first exemplary embodiment, illustrating the cross section of an inlet (outlet) passage;

FIG. 4 is another enlarged side view of the part of the first exemplary embodiment, illustrating another cross section of the inlet (outlet) passage;

FIG. 5 is a schematic sectional view of a second exemplary embodiment of the apparatus according to the present invention;

FIG. 6 is a schematic sectional view of a third exemplary embodiment of the apparatus according to the present invention; and

FIG. 7 is a schematic sectional view of a fourth exemplary embodiment of the apparatus according to the present invention.

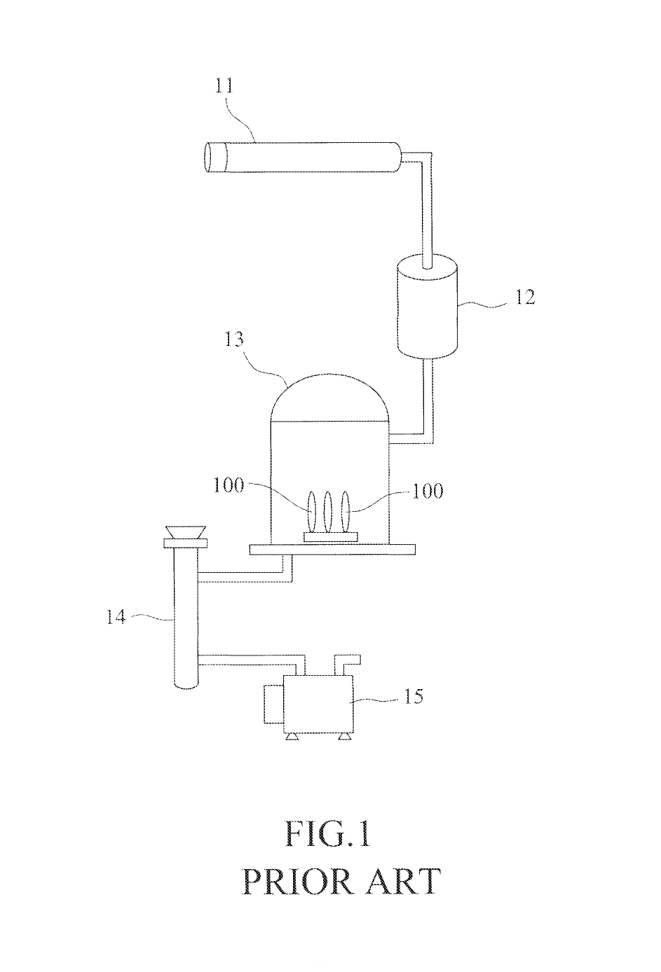

### DETAILED DESCRIPTION OF THE EXEMPLARY EMBODIMENTS

Before the present invention is described in greater detail, it should be noted that like elements are denoted by the same reference numerals throughout the disclosure.

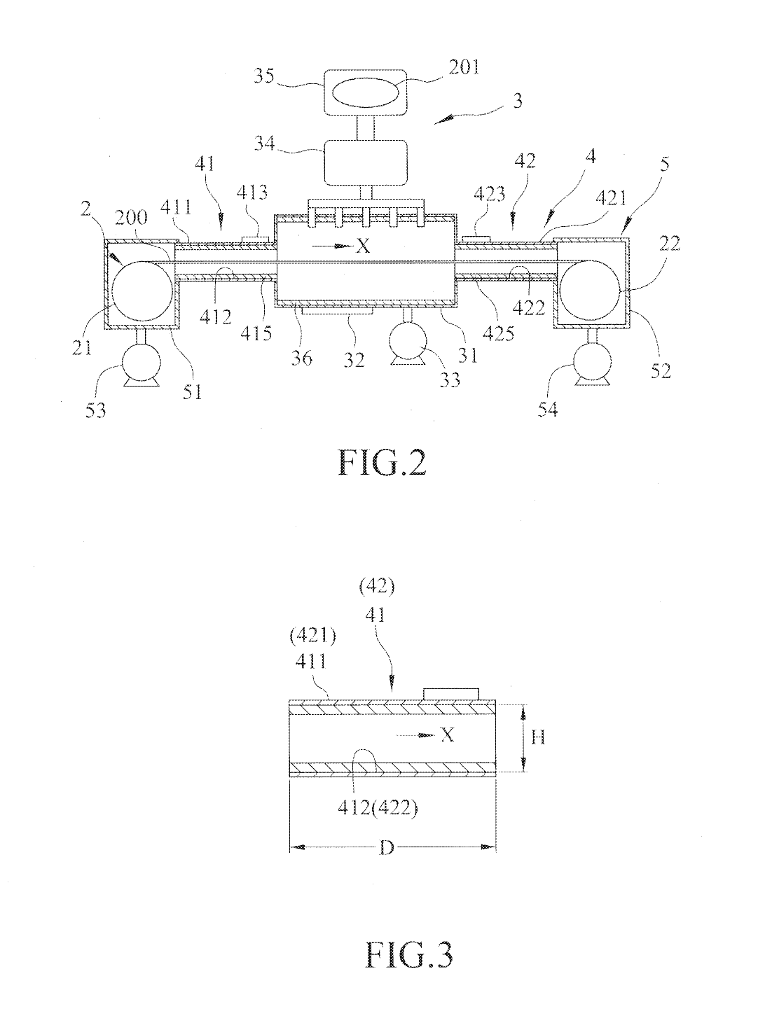

Referring to FIG. 2, the first exemplary embodiment of an apparatus for continuously forming a film through chemical vapor deposition according to the present invention is shown to include a conveyor unit 2, a depositing unit 3, a cooling mechanism 4 and a substrate handling unit 5.

The conveyor unit 2 is for conveying a substrate 200 along a moving path (X). In this embodiment, the conveyor unit 2 is configured as a roll-to-roll mechanism and includes a substrate supply roller 21 and a take-up roller 22. The substrate 200 may be a soft substrate and examples thereof may be, but are not limited to, flexible textiles, non-woven fabrics, polymer sheets and the like. In other embodiments, the substrate 200 may be a rigid substrate and the conveyor unit 2 is a conveyor belt.

The depositing unit 3 includes a deposition chamber 31 disposed on the moving path (X) to deposit a film-forming material on the substrate 200. In this embodiment, one deposition chamber 31 is adopted. In this embodiment, the depositing unit 3 further includes a deposition chamber heater 32 for heating an inner surface of the deposition chamber 31, a deposition chamber pump 33 connected fluidly to the deposition chamber 31 for producing a vacuum pressure in the deposition chamber 31, a material decomposition chamber 34 connected fluidly to the deposition chamber 31, and a material vaporizer 35 connected fluidly to the material decomposition chamber 34 and receiving precursors 201 of the film-forming material (e.g., solid di-para-xylylene). It is worth noting that, as shown in FIG. 2, the depositing unit 3 may further include a replacement shield 36 that is removably disposed inside the deposition chamber 31 and that covers the inner surface of the deposition chamber 31 for preventing the film-forming material, which enters the deposition chamber 31, from depositing on the inner surface of the deposition chamber 31. In this embodiment, the deposition chamber heater 32 is operable to heat the inner surface of the deposition chamber 31 to about 100° C. In this embodiment, the film is made of poly-para-xylylene, and the film-forming material is para-xylylene. However, the film-forming material is not limited thereto in other embodiments according to the present invention. Based on various film-forming materials, the material decomposition chamber 34 and/or the material vaporizer 35 may be omitted in other embodiments in accordance with the present invention.

The cooling mechanism 4 includes an inlet cooling unit 41 communicated fluidly with the deposition chamber 31, and an outlet cooling unit 42 communicated fluidly with the deposition chamber 31. The inlet and outlet cooling units 41, 42 are respectively disposed at two opposite sides of the deposition chamber 31 and are controllable to provide a cooling temperature that prevents the film-forming material from escaping and scattering away from the inlet and outlet cooling units 41, 42.

In this embodiment, the inlet cooling unit 41 includes an inlet chamber 411 communicated fluidly with the deposition chamber 31 by way of an inlet passage 412, and an inlet cooler 413 to control the cooling temperature in the inlet chamber 411. Similarly, the outlet cooling unit 42 includes an outlet chamber 421 communicated fluidly with the deposition chamber 31 by way of an outlet passage 422, and an outlet cooler 423 to control the cooling temperature in the outlet chamber 421. It should be noted that, in this embodiment, the inlet cooling unit 41 may further include an inlet sleeve 415 removably disposed in the inlet passage 412 to cover an inner surface of the inlet chamber 411 for preventing the film-forming material, which enters the inlet chamber 411, from depositing on the inner surface of the inlet chamber 411. Similarly, the outlet cooling unit 42 may include an outlet sleeve 425 removably disposed in the outlet passage 422 to cover an inner surface of the outlet chamber 421 for preventing the film-forming material, which enters the outlet chamber 421, from depositing on the inner surface of the outlet chamber 421. In this embodiment, the cooling temperature of each of the inlet and outlet t chambers 411, 421 ranges from −100° C. to −20° C. which is low enough to induce condensation of the film-forming material.

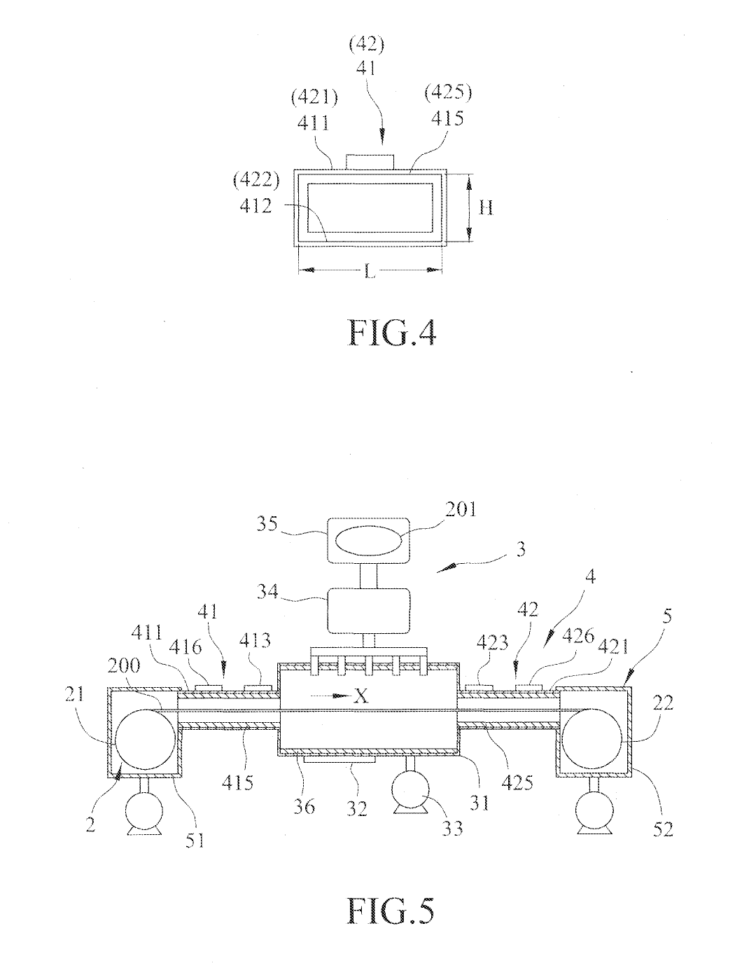

As shown in FIGS. 3 and 4, in this embodiment, each of the inlet and outlet passages 412, 422 extends along the moving path (X) and has a first dimension (D) that is in a range of from 0.1 to 1 meter along the moving path (X), a second dimension (H) that is perpendicular to the first dimension (D) and that is in a range of from 0.02 to 0.2 meters, and a third dimension (L) that is perpendicular to the first and second dimensions (D), (H) and that is in a range of from 0.1 to 2.5 meters.

As shown in FIG. 2, the substrate handling unit 5 includes a substrate supply chamber 51 that is connected to the inlet chamber 411 and that has the substrate supply roller 21 disposed therein, a substrate take-up chamber 52 that is connected to the outlet chamber 421 and that has the substrate take-up roller 22 disposed therein, a supply chamber vacuum pump 53 connected to the substrate supply chamber 51, and a take-up chamber vacuum pump 54 connected to the substrate take-up chamber 52.

When in use, two opposite sides of the substrate 200 are connected respectively to the substrate supply roller 21 and the substrate take-up roller 22. Thereafter, the deposition chamber 31, together with the material decomposition chamber 34, the material vaporizer 35, the inlet chamber 411 and the outlet chamber 412, is vacuumed utilizing the deposition chamber pump 33 to a vacuum pressure of lower than 5×10⁻² torr. The substrate supply chamber 51 and the substrate take-up chamber 52 are vacuumed respectively by the supply chamber vacuum pump 53 and the take-up chamber vacuum pump 54 to a vacuum pressure of lower than 5×10⁻² torr.

Subsequently, the material vaporizer 35 is heated to 150° C. to vaporize the precursors 201 of the film-forming material (i.e., solid di-para-xylylene in this embodiment), and the material decomposition chamber 34 is heated to 650° C. to decompose the vaporized precursors into the vaporized film-forming material (i.e., para-xylylene monomers in this embodiment). In the meantime, the inlet and outlet coolers 413, 423 are utilized to lower the temperatures respectively in the inlet and outlet chambers 411, 421 to the cooling temperature of below −20° C. for inducing condensation of the vaporized film-forming material, which is later introduced into the deposition chamber 31 from the material decomposition chamber 34, on the inlet and outlet sleeves 415, 425, thereby preventing the film-forming material from escaping and scattering away from the deposition chamber 31 through the inlet and outlet chambers 411, 421. In addition, by virtue of the dimensions of the inlet and outlet passages 412, 422, the probability of the vaporized film-forming material escaping and scattering away from the inlet and outlet chambers 411, 421 can further be lowered effectively.

Thereafter, the inner surface of the deposition chamber 31 is heated to about 100° C., and the vaporized film-forming material is then introduced into the deposition chamber 31 from the material decomposition chamber 34. The substrate 200 is then conveyed consecutively by the substrate supply roller 21 and the substrate take-up roller 22 of the conveyor unit 2 to pass through the inlet cooling unit 41, to enter the deposition chamber 31, and to pass through and out of the outlet cooling unit 42, so that the film-forming material is continuously deposited on the substrate 200 (i.e., forming a poly-para-xylylene film on the substrate 200 in this embodiment). It is worth noting that, due to the existence of the replacement shield 36, heat radiation from the inner surface of the deposition chamber 31 is effectively blocked and has no or little influence on the film deposition. Moreover, the heated inner surface of the deposition chamber 31 may effectively reduce the probability of deposition of the film-forming material thereon.

It is worth noting that after long-term use of the apparatus in accordance with the present invention, some film-forming material may deposit outside of the substrate 200, e.g., on the replacement shield 36 and/or on the inlet and outlet sleeves 415, 425, if needed, the replacement shield 36 and/or the inlet and outlet sleeves 415, 425 may be replaced without otherwise having unusable deposition chamber 31 and inlet and outlet chambers 411, 421 should there be no replacement shield 36 and the inlet and outlet sleeves 415, 425 to cover the inner surfaces of the deposition chamber 31 and inlet and outlet chambers 411, 421. As such, the apparatus can have prolonged service life, and the production cost for deposition of the film can be effectively reduced.

Referring to FIG. 5, the second exemplary embodiment of the apparatus according to the present invention is shown to be similar to the first exemplary embodiment. The difference therebetween resides in that the inlet cooling unit 41 of the second exemplary embodiment further includes an inlet heater 416 to heat the inlet chamber 411 and to prevent generation of a condensate in the inlet chamber 411. The outlet cooling unit 42 of the second exemplary embodiment further includes an outlet heater 426 to heat the outlet chamber 421 and to prevent generation of a condensate in the outlet chamber 421. To be specific, when the film deposition process is finished, the inlet and outlet heaters 416, 426 may respectively heat the inlet and outlet chambers 411, 421 to a temperature which is not smaller than the ambient temperature and not larger than 100° C. prior to dismissal of the vacuum condition in the inlet and outlet chambers 411, 421, so as to prevent the generation of a condensate therein.

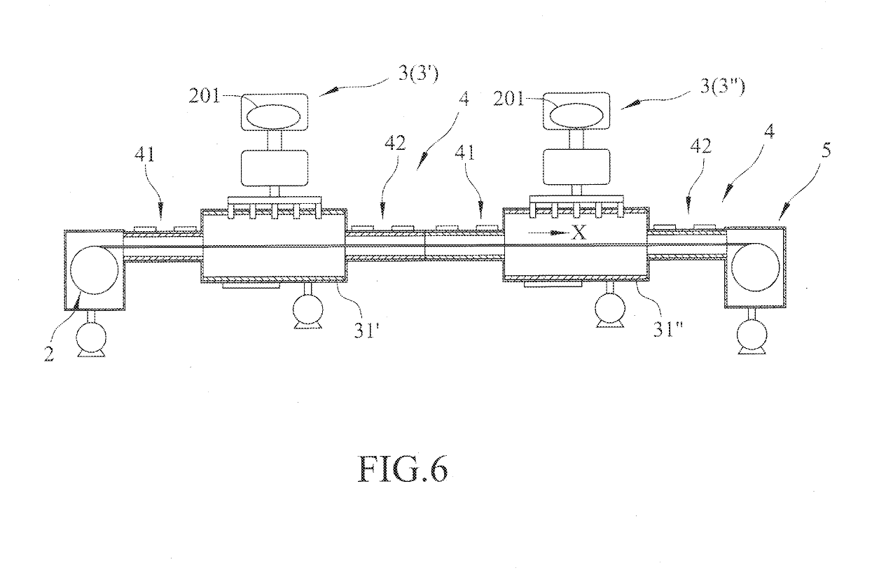

Referring to FIG. 6, the third exemplary embodiment of the apparatus according to the present invention is shown to be similar to the second exemplary embodiment, with the only difference therebetween residing in adoption of a plurality of the depositing units 3. To be specific, the apparatus of this embodiment includes an upstream depositing unit 3′ having an upstream deposition chamber 31′, and a downstream depositing unit 3″ having a downstream deposition chamber 31″. The upstream and downstream deposition chambers 31′, 31″ are disposed in series along the moving path (X). In this embodiment, the cooling mechanism 4 includes two sets of the inlet and outlet cooling units 41, 42 each of which is coupled to a respective one of the upstream and downstream deposition chambers 31′, 31″. In addition, the outlet cooling unit 42 corresponding to the upstream deposition chamber 31′ is connected fluidly to the inlet cooling unit 42 corresponding to the downstream deposition chamber 31″. By incorporating the multiple depositing units 3 into the design of the apparatus according to the present invention, various or similar film deposition processes can be conducted simultaneously to form a multilayered structure on the substrate 200. It should be noted that, in other embodiments, instead of having the multiple depositing units 3, one single depositing unit 3 including a plurality of the deposition chambers 31 may be employed according to the present invention.

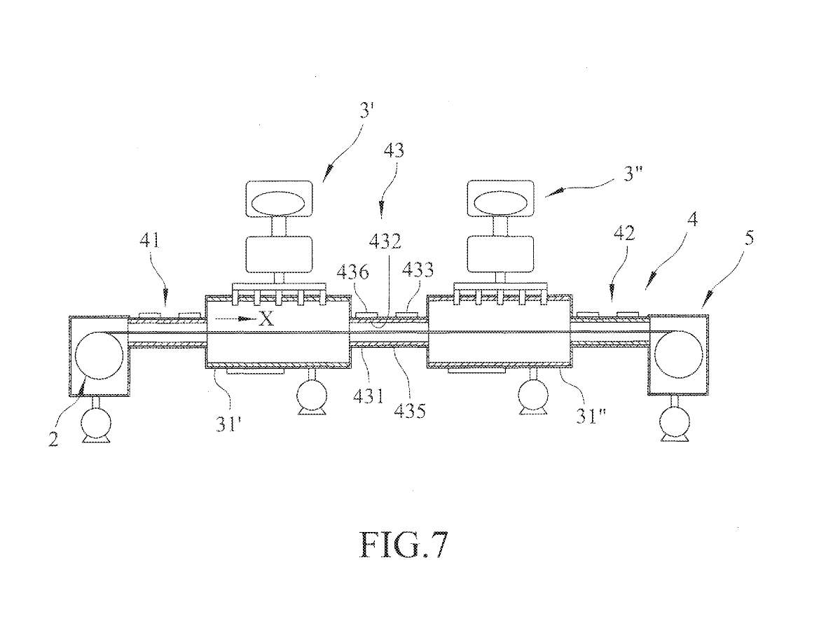

Referring to FIG. 7, the fourth exemplary embodiment of the apparatus according to the present invention is shown to be similar to the third exemplary embodiment. The difference therebetween resides in that, in the fourth exemplary embodiment, the cooling structure 4 only includes one inlet cooling unit 41 that is connected to an inlet of the upstream deposition chamber 31′, and one outlet cooling unit 42 that is connected to an outlet of the downstream deposition chamber 31″. The cooling mechanism 4 further includes an intermediate cooling unit 43 that is connected to an outlet of the upstream deposition chamber 31′ and an inlet of the downstream deposition chamber 31″ and that is controllable to maintain at the cooling temperature as the inlet and outlet cooling units 41, 42. In greater detail, the intermediate cooling unit 43 has an intermediate chamber 431 defining an intermediate passage 432 and connected fluidly to the upstream and downstream deposition chambers 31′, 31″, and an intermediate cooler 433 to control the cooling temperature in the intermediate chamber 431. Similar to the inlet and outlet cooling units 41, 42, the cooling temperature of the intermediate chamber 431 may be not larger than −20° C. and not smaller than −100° C. The intermediate cooling unit 43 may further have an intermediate sleeve 435 removably disposed inside the intermediate passage 432 and covering an inner surface of the intermediate chamber 431. In addition, the intermediate cooling unit 43 may further have an intermediate heater 436 to heat the intermediate chamber 431 to an elevated temperature of not smaller than an ambient temperature and not larger than 100° C.

To sum up, by utilizing the conveyor unit 2 to convey the substrate 200 along the moving path (X) to consecutively pass through the deposition chamber 31, the apparatus of the present invention can continuously deposit a film on different parts of the substrate 200 and thus have improved production efficiency. In addition, by incorporating the cooling mechanism 4 into the apparatus of the present invention, leakage of the vaporized film-forming material can be effectively prevented.

While the present invention has been described in connection with what are considered the most practical embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An apparatus for continuously forming a film through chemical vapor deposition, comprising:
a conveyer unit for conveying a substrate along a moving path;
at least one depositing unit including a deposition chamber disposed on said moving path to deposit a film-forming material on the substrate; and
a cooling mechanism including an inlet cooling unit communicated fluidly with said deposition chamber, and an outlet cooling unit communicated fluidly with said deposition chamber, said inlet and outlet cooling units being respectively disposed at two opposite sides of said deposition chamber and being controllable to provide a cooling temperature that prevents the film-forming material from escaping and scattering away from said inlet and outlet cooling units; and
wherein said conveyer unit conveys the substrate to consecutively pass through said inlet cooling unit, said deposition chamber and said outlet cooling unit so that the film-forming material is able to deposit on the substrate in said deposition chamber.

2. The apparatus as claimed in claim 1, wherein said inlet cooling unit includes an inlet chamber communicated fluidly with said deposition chamber, and an inlet cooler to control said cooling temperature in said inlet chamber, and said outlet cooling unit includes an outlet chamber communicated fluidly with said deposition chamber, and an outlet cooler to control said cooling temperature in said outlet chamber.

3. The apparatus as claimed in claim 2, wherein said inlet cooling unit further includes an inlet sleeve removably disposed inside and covering an inner surface of said inlet chamber for preventing the film-forming material that enters said inlet chamber from depositing on said inner surface of said inner chamber, said outlet cooling unit further including an outlet sleeve removably disposed inside and covering an inner surface of said outlet chamber for preventing said film-forming material that enters said outlet chamber from depositing on said inner surface of said outlet chamber.

4. The apparatus as claimed in claim 3, wherein said depositing unit further includes a deposition chamber heater for heating an inner surface of said deposition chamber, and a deposition chamber pump connected fluidly to said deposition chamber for producing a vacuum pressure in said deposition chamber.

5. The apparatus as claimed in claim 4, wherein said depositing unit further includes a material decomposition chamber connected fluidly to said deposition chamber, and a material vaporizer connected fluidly to said material decomposition chamber.

6. The apparatus as claimed in claim 5, wherein said depositing unit further includes a replacement shield removably disposed inside and covering an inner surface of said deposition chamber for preventing the film-forming material that enters said deposition chamber from depositing on said inner surface of said deposition chamber.

7. The apparatus as claimed in claim 6, wherein said deposition chamber heater is operable to heat said inner surface of said deposition chamber to about 100° C.

8. The apparatus as claimed in claim 2, wherein the film-forming material is para-xylylene, and each of said inlet and outlet chambers has a cooling temperature ranging from −100° C. to −20° C.

9. The apparatus as claimed in claim 2, wherein said inlet cooling unit further includes an inlet heater to heat said inlet chamber and to prevent the generation of a condensate in said inlet chamber, and an outlet heater to heat said outlet chamber and prevent the generation of a condensate in said outlet chamber.

10. The apparatus as claimed in claim 9, wherein said inlet and outlet heaters respectively heat said inlet and outer chambers to a temperature not smaller than an ambient temperature and not larger than 100° C.

11. The apparatus as claimed in claim 3, wherein said inlet chamber defines an inlet passage that extends along said moving path and that receives said inlet sleeve, said outlet chamber defining an outlet passage that extends along said moving path and that receives said outlet sleeve, each of said inlet and outlet passages having a first dimension along said moving path, a second dimension perpendicular to said first dimension, and a third dimension perpendicular to said first and second dimensions, said first dimension being in a range of from 0.1 to 1 meter, said second dimension being in a range of from 0.02 to 0.2 meters, said third dimension being in a range of from 0.1 to 2.5 meters.

12. The apparatus as claimed in claim 2, further comprising a substrate handling unit which includes a substrate supply chamber connected to said inlet chamber, a substrate take-up chamber connected to said outlet chamber, a supply chamber vacuum pump connected to said substrate supply chamber, and a take-up chamber vacuum pump connected to said substrate take-up chamber, said conveyer unit including a substrate supply roller disposed in said substrate supply chamber, and a take-up roller disposed in said substrate take-up chamber.

13. The apparatus as claimed in claim 1, wherein said at least one depositing unit includes an upstream depositing unit having an upstream deposition chamber that is disposed on said moving path, and a downstream depositing unit having a downstream deposition chamber that is disposed on said moving path, said inlet cooling unit being connected to an inlet of said upstream deposition chamber, said outlet cooling unit being connected to an outlet of said downstream deposition chamber, said cooling mechanism further including an intermediate cooling unit that is connected to an outlet of said upstream deposition chamber and an inlet of said downstream deposition chamber and that is controllable to maintain said cooling temperature.

14. The apparatus as claimed in claim 13, wherein said intermediate cooling unit has an intermediate chamber defining an intermediate passage and connected fluidly to said upstream and downstream deposition chambers, and an intermediate cooler to control said cooling temperature in said intermediate chamber.

15. The apparatus as claimed in claim 14, wherein said intermediate cooling unit further has an intermediate sleeve removably disposed inside said intermediate passage and covering an inner surface of said intermediate chamber.

16. The apparatus as claimed in claim 14, wherein said cooling temperature of said intermediate chamber is not larger than −20° C. and not smaller than −100° C.

17. The apparatus as claimed in claim 13, wherein said intermediate cooling unit further has an intermediate heater to heat said intermediate chamber to an elevated temperature of not smaller than an ambient temperature and not larger than 100° C.
